(19) United States
(12) Patent Application Publication
(10) Pub. No.: US 2014/0232449 A1
(43) Pub. Date: Aug. 21, 2014

(54) POWER GATING CIRCUITS USING SCHMITT TRIGGER CIRCUITS, SEMICONDUCTOR INTEGRATED CIRCUITS AND SYSTEMS INCLUDING THE POWER GATING CIRCUITS

(71) Applicant: Young-min SHIN, Seoul (KR)

(72) Inventor: Young-min SHIN, Seoul (KR)

(21) Appl. No.: 14/171,829

(22) Filed: Feb. 4, 2014

(30) Foreign Application Priority Data
Feb. 21, 2013 (KR) 10-2013-0018836

(51) Int. Cl. H03K 3/012; H03K 17/16

(52) U.S. Cl. CPC H03K 3/012; H03K 17/164
USPC 327/427

(57) ABSTRACT

A power gating circuit is configured to connect a first voltage line to a second voltage line or separate the first voltage line from the second voltage line using a Schmitt trigger circuit that is configured to detect a voltage level of the second voltage line. The voltage lines are power lines or ground lines.

### CROSS-REFERENCE TO RELATED APPLICATIONS

This application claims priority under 35 U.S.C. §119 to Korean Patent Application No. 10-2013-0018836, filed on Feb. 21, 2013, in the Korean Intellectual Property Office, the disclosure of which is incorporated herein in its entirety by reference.

### BACKGROUND

1. Field

Example embodiments of inventive concepts relate to semiconductor integrated circuits, and more particularly, to power gating circuits using Schmitt trigger circuits, semiconductor integrated circuits including power gating circuits, and/or systems including power gating circuits.

2. Description of Conventional Art

Semiconductor integrated circuits pursue low power consumption, and include a circuit for partially controlling a power supply of an internal circuit, which is called a power gating circuit. The power gating circuit is designed so that a recovery of a power supply voltage of the internal circuit is completed within a predetermined time. When a recovery time is shortened, a power noise occurs in a power line of the internal circuit because a current rapidly flows through a stabilization capacitor equipped together with the internal circuit when returning from a power-down state to a power-on state. The power noise causes a malfunction of a semiconductor integrated circuit, and thus, it is necessary to suppress or prevent the generation of the power noise.

### SUMMARY

Example embodiments of inventive concepts provide power gating circuits using Schmitt trigger circuits, semiconductor integrated circuits including power gating circuits, and systems including power gating circuits.

According to an example embodiment of inventive concepts, there is provided a power gating circuit including: a first power line; a second power line; a first switching circuit configured to connect the first power line to the second power line or separate the first power line from the second power line in response to a first control signal indicative of a power-on or a power-off state of a logic circuit; a control signal generation circuit configured to generate a second control signal in response to the first control signal and an output signal of a Schmitt trigger circuit that is configured to detect a voltage level of the second power line; and a second switching circuit configured to connect the first power line to the second power line or separate the first power line from the second power line in response to the second control signal.

According to an example embodiment of inventive concepts, there is provided a semiconductor integrated circuit including: a first power line; a second power line; and a power gating circuit configured to connect the first power line to the second power line or separate the first power line from the second power line and use a Schmitt trigger circuit that is configured to detect a voltage level of the second power line.

The first power line may be connected to an external power supply. The second power line may be connected to a power supply of a logic circuit included in the semiconductor integrated circuit.

A driving capability of the first switching circuit may be smaller than a driving capability of the second switching circuit.

The first switching circuit may include at least one (e.g., p-type metal oxide semiconductor (PMOS)) transistor, wherein a gate of the at least one transistor is configured to receive the first control signal, a source of the at least one transistor is connected to the first power line, and a drain of the at least one transistor is connected to the second power line.

The control signal generation circuit may include: the Schmitt trigger circuit, wherein the Schmitt trigger circuit has an input terminal that is connected to the second power line; and a logic gate circuit (e.g., an OR gate) configured to receive the first control signal and the output signal from the Schmitt trigger circuit, the logic gate circuit being further configured to output the second control signal.

The Schmitt trigger circuit may include: a first (e.g., PMOS) transistor, a second (e.g., PMOS) transistor, a third (e.g., n-type metal oxide semiconductor (NMOS)) transistor and a fourth (e.g., NMOS) transistor, which are serially connected between a power supply voltage and a ground voltage; a first connection node between the first transistor and the second transistor; a second connection node between the second transistor and the third transistor; a third connection node between the third transistor and the fourth transistor; a first inverter connected to the second connection node; a fifth (e.g., PMOS) transistor connected to the power supply voltage and the first connection node; a sixth (e.g., NMOS) transistor, connected to the ground voltage and the third connection node; and a second inverter connected between an output node of the first inverter and the output signal of the Schmitt trigger circuit.

The second switching circuit may include at least one (e.g., PMOS) transistor, wherein a gate of the at least one transistor is configured to receive the second control signal, a source of the at least one transistor is connected to the first power line, and a drain of the at least one transistor is connected to the second power line.

According to another example embodiment of inventive concepts, there is provided a semiconductor integrated circuit including: a first ground line; a second ground line; and a power gating circuit configured to connect the first ground line to the second ground line or separate the first ground line from the second ground line and to use a Schmitt trigger circuit that is configured to detect a voltage level of the second ground line.

The first ground line may be connected to an external ground voltage. The second ground line may be connected to a ground voltage of a logic circuit included in the semiconductor integrated circuit.

The power gating circuit may include: a first switching circuit configured to connect the first ground line to the second ground line or separate the first ground line from the second ground line in response to a first control signal indicative of a ground-on or ground-off state of the logic circuit; a control signal generation circuit configured to generate a second control signal in response to the first control signal and an output signal from the Schmitt trigger circuit that is connected to the second ground line; and a second switching circuit configured to connect the first ground line to the second ground line or separate the first ground line from the second ground line in response to the second control signal.

The first switching circuit may include at least one (e.g., NMOS) transistor, wherein a gate of the at least one transistor is configured to receive the first control signal, a source of the at least one transistor is connected to the first ground line, and a drain of the at least one transistor is connected to the second ground line.

The control signal generation circuit may include: the Schmitt trigger circuit having an input terminal connected to the second ground line; and a logic gate circuit (e.g., an AND gate) configured to receive the first control signal and the output signal from the Schmitt trigger circuit, the logic gate circuit being further configured to output the second control signal.

The second switching circuit may include at least one (e.g., NMOS) transistor, wherein a gate of the at least one transistor is configured to receive the second control signal, a source of the at least one transistor is connected to the first ground line, and a drain of the at least one transistor is connected to the second ground line.

According to another example embodiment of inventive concepts, there is provided a system including: a logic circuit; a first power line connected to an external power supply; a first ground line connected to an external ground voltage; and a power gating circuit configured to: use a Schmitt trigger circuit to detect a voltage level of a second power line or a second ground line of the logic circuit; connect the first power line to the second power line or separate the first power line from the second power line; and connect the first ground line to the second ground line or separate the first ground line from the second ground line.

According to another example embodiment of inventive concepts, there is provided a power gating circuit including: a first switching circuit configured to selectively connect a first voltage line and a second voltage line in response to a first control signal; a Schmitt trigger circuit configured to generate an output signal based on a detected voltage level of the second voltage line; a control signal generation circuit configured to generate a second control signal in response to the first control signal and the output signal from the Schmitt trigger circuit; and a second switching circuit configured to selectively connect the first voltage line and the second voltage line in response to the second control signal. The first and second voltage lines may be power lines or ground lines.

The Schmitt trigger circuit may be configured to generate the output signal having a first logic level when the voltage level reaches a first voltage trigger point, and to generate the output signal having a second logic level when the voltage level reaches a second voltage trigger point. The first voltage trigger point may be greater than the second voltage trigger point, and the first logic level may be different from the second logic level.

According to another example embodiment of inventive concepts, there is provided a system including: a logic circuit; and a power gating circuit configured to apply an operating voltage to the logic circuit. The power gating circuit includes: a first switching circuit configured to selectively connect a first voltage line and a second voltage line in response to a first control signal; a control signal generation circuit configured to generate a second control signal in response to the first control signal and an output signal from a Schmitt trigger circuit configured to generate the output signal based on a detected voltage level of the second voltage line; and a second switching circuit configured to selectively connect the first voltage line and the second voltage line in response to the second control signal. The first and second voltage lines may be power lines or ground lines

### BRIEF DESCRIPTION OF THE DRAWINGS

Example embodiments of inventive concepts will be more clearly understood from the following detailed description taken in conjunction with the accompanying drawings in which:

FIG. 1 is a diagram of a semiconductor integrated circuit including a power gating circuit according to an example embodiment of inventive concepts;

FIG. 2 is a diagram illustrating an example operation waveform of a Schmitt trigger circuit of FIG. 1;

FIG. 3 is a diagram illustrating example operation of the power gating circuit of FIG. 1;

FIG. 4 is a circuit diagram of an example embodiment of the Schmitt trigger circuit of FIG. 1;

FIG. 5 is a diagram of a semiconductor integrated circuit including a power gating circuit according to another example embodiment of inventive concepts;

FIG. 6 is a diagram illustrating an example operation waveform of a Schmitt trigger circuit of FIG. 5;

FIG. 7 is a diagram illustrating example operation of the power gating circuit of FIG. 5;

FIG. 8 is a block diagram of a system including a power gating circuit, according to an example embodiment of inventive concepts; and

FIG. 9 is a block diagram of a system including a power gating circuit, according to another example embodiment of inventive concepts.

### DETAILED DESCRIPTION

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms used herein include technical terms and scientific terms, and also have the same meanings that those of ordinary skill in the art commonly understand. Additionally, it should be understood that typically used terms defined in dictionaries have consistent meanings in related technical contents, and if not explicitly defined, should not be interpreted as being excessive formal meanings.

The terms used in the present specification are merely used to describe particular embodiments, and are not intended to limit the inventive concept. An expression used in the singular encompasses the expression of the plural, unless it has a clearly different meaning in the context. In the present specification, it is to be understood that the terms such as “including” or “having,” etc., are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. As used herein, the term “and/or” includes any and all combinations of one or more of the associated listed items.

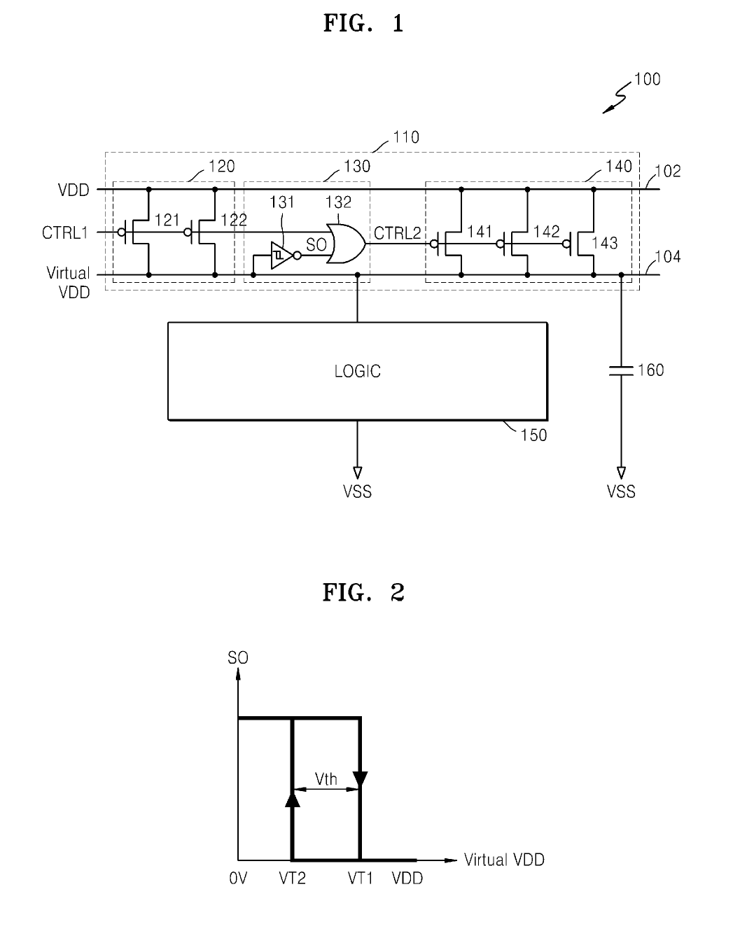

FIG. 1 is a diagram of a semiconductor integrated circuit 100 including a power gating circuit according to an example embodiment of inventive concepts.

Referring to FIG. 1, the semiconductor integrated circuit 100 includes a power gating circuit 110, which is connected between a first power line 102 and a second power line 104, and a logic circuit 150. The first power line 102 is connected to an external power supply VDD, and the second power line 104 is coupled to the first power line 102 through the power gating circuit 110 and is connected to a power supply VIRTUAL VDD of the logic circuit 150. The power supply VIRTUAL VDD of the logic circuit 150 may be set to have the same or substantially the same voltage level as the external power supply VDD. The power supply VIRTUAL VDD of the logic circuit 150 may be referred to as a virtual power supply.

The power gating circuit 110 includes a first switching circuit 120, a control signal generation circuit 130, and a second switching circuit 140. The first switching circuit 120 includes one or more p-type metal oxide semiconductor (PMOS) transistors 121 and 122 that are connected between the first power line 102 and the second power line 104. Gates of the PMOS transistors 121 and 122 are connected to a first control signal CTRL1.

The first control signal CTRL1 may be provided by a central processing unit (CPU) according to the need for operation of the logic circuit 150. That is, the CPU may determine whether the operation of the logic circuit 150 is needed and then provide, based on the determination, the first control signal CTRL1 to power-on or power-off the logic circuit 150. The first control signal CTRL1 may be provided at a logic low level so that the logic circuit 150 enters into a power-on state, and may be provided at a logic high level so that the logic circuit 150 enters into a power-off state.

In the first switching circuit 120, the PMOS transistors 121 and 122 are turned on in response to the first control signal CTRL1 transitioning to a logic low level, and the external power supply VDD of the first power line 102 is transmitted to the virtual power supply VIRTUAL VDD of the second power line 104 through the turned-on PMOS transistors 121 and 122. The PMOS transistors 121 and 122 are turned off in response to the first control signal CTRL1 transitioning to a logic high level, and the external power supply VDD of the first power line 102 is cut off from the virtual power supply VIRTUAL VDD of the second power line 104 by the turned-off PMOS transistors 121 and 122.

The control signal generation circuit 130 includes a Schmitt trigger circuit 131 that is connected to the second power line 104, and an OR gate (also referred to herein as a logic gate circuit) 132 that receives the first control signal CTRL1 and an output signal SO of the Schmitt trigger circuit 131. The Schmitt trigger circuit 131 has a voltage level detection function using hysteresis characteristics.

FIG. 2 is a diagram illustrating an example operation waveform of the Schmitt trigger circuit 131. As shown in FIG. 2, the Schmitt trigger circuit 131 has two trigger points, e.g., first and second trigger points VT1 and VT2, according to a voltage level of the virtual power supply VIRTUAL VDD of the second power line 104. According to the hysteresis characteristics, the first trigger point VT1 occurring when the voltage level of the virtual power supply VIRTUAL VDD rises from a low value to a high value is higher than the second trigger point VT2 occurring when the voltage level of the virtual power supply VIRTUAL VDD falls from the high value to the low value. The Schmitt trigger circuit 131 may generate the output signal SO at a logic low level at the first trigger point VT1, and may generate the output signal SO at a logic high level at the second trigger point VT2.

The OR gate 132 receives the output signal SO of the Schmitt trigger circuit 131 and the first control signal CTRL1, and outputs a second control signal CTRL2. A voltage level of the second control signal CTRL2 transitions to a logic low level in response to the output signal SO transitioning to a logic low level at the first trigger point VT1 while the first control signal CTRL1 is at a logic low level, which results in the power-on state of the logic circuit 150. The voltage level of the second control signal CTRL2 transitions to a logic high level in response to the output signal SO transitioning to a logic high level at the second trigger point VT2 while the first control signal CTRL1 is at a logic low level, which results in the power-on state of the logic circuit 150. Also, the voltage level of the second control signal CTRL2 transitions to a logic high level in response to the first control signal CTRL1 transitioning to a logic high level, which results in the power-off state of the logic circuit 150.

The second switching circuit 140 includes one or more PMOS transistors 141, 142, and 143 that are connected between the first power line 102 and the second power line 104. Gates of the PMOS transistors 141, 142, and 143 are connected to the second control signal CTRL2. In the second switching circuit 140, the PMOS transistors 141, 142, and 143 are turned on in response to the second control signal CTRL2 transitioning to a logic low level, and the external power supply VDD of the first power line 102 is transmitted to the virtual power supply VIRTUAL VDD of the second power line 104 through the turned-on PMOS transistors 141, 142, and 143. The PMOS transistors 141, 142, and 143 are turned off in response to the second control signal CTRL2 transitioning to a logic high level, and the external power supply VDD of the first power line 102 is cut off from the virtual power supply VIRTUAL VDD of the second power line 104 by the turned-off PMOS transistors 141, 142, and 143.

The PMOS transistors 121, 122, 141, 142, and 143, which constitute the first and second switching circuits 120 and 140 of the power gating circuit 110, may be referred to as power gating cells (PGCs).

The logic circuit 150 may be composed of, for example, any one of various intellectual property (IP) blocks that are embedded in a system such as a mobile terminal. The mobile terminal may be a mobile phone, a personal mobile terminal, a mobile personal computer (PC), etc. The mobile terminal may provide various functions, such as a multimedia function for reproducing music, movies, camera images, etc. and a function for sending and receiving text messages and voice messages, as well as a voice call function and a video call function.

A stabilization capacitor 160 is connected between the second power line 104, to which the virtual power supply VIRTUAL VDD of the logic circuit 150 is connected, and a ground voltage VSS. The stabilization capacitor 160 prevents a noise occurring in the virtual power supply VIRTUAL VDD from influencing an operation of the logic circuit 150.

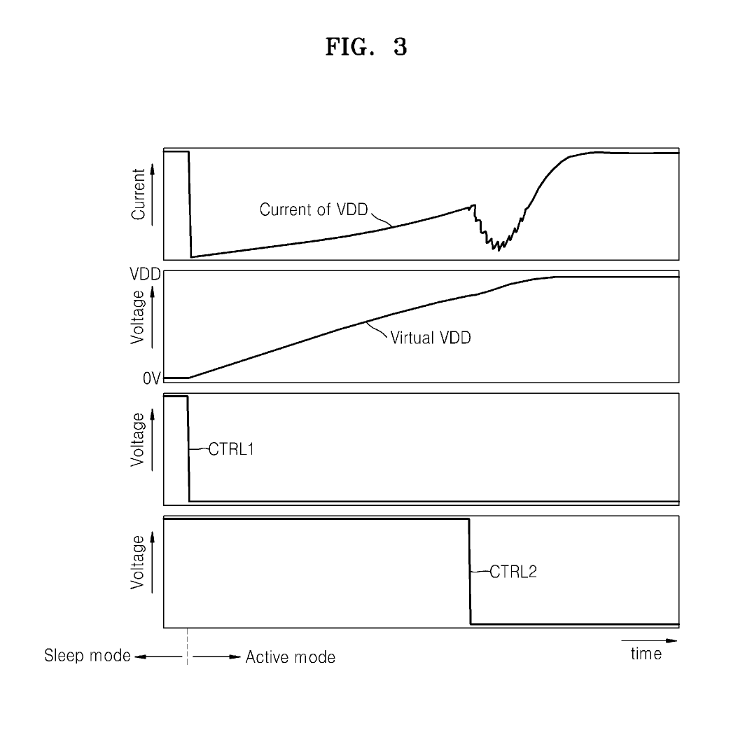

FIG. 3 is a diagram illustrating an electrical potential of the virtual power supply VIRTUAL VDD according to the example operation of the power gating circuit 110 of FIG. 1.

Referring to FIG. 3, a voltage level of the first control signal CTRL1 transitions to a logic high level when a sleep mode is activated in which the logic circuit 150 is in the power-off state. A voltage level of the second control signal CTRL2 also transitions to a logic high level when the first control signal CTRL1 transitions to a logic high level. Accordingly, the PMOS transistors 121 and 122 of the first switching circuit 120 and the PMOS transistors 141, 142, and 143 of the second switching circuit 140 are turned off, and thus, the first power line 102 and the second power line 104 are cut off from each other.

Then, the voltage level of the first control signal CTRL1 transitions to a logic low level when an active mode is activated in which the logic circuit 150 is in the power-on state. The PMOS transistors 121 and 122 of the first switching circuit 120 are turned on in response to the first control signal CTRL1 transitioning to a logic low level. The external power supply VDD of the first power line 102 is supplied to the virtual power supply VIRTUAL VDD of the second power line 104 through the turned-on PMOS transistors 121 and 122, and thus, a voltage level of the virtual power supply VIRTUAL VDD gradually increases.

When the voltage level of the virtual power supply VIRTUAL VDD increases and then reaches the first trigger point VT1 of the Schmitt trigger circuit 131, the voltage level of the second control signal CTRL2 that is generated from the control signal generation circuit 130 transitions to a logic low level. The PMOS transistors 141, 142, and 143 of the second switching circuit 140 are turned on in response to the second control signal CTRL2 transitioning to a logic low level. The external power supply VDD of the first power line 102 is additionally supplied to the virtual power supply VIRTUAL VDD of the second power line 104 through the turned-on PMOS transistors 141, 142, and 143. Thus, the voltage level of the virtual power supply VIRTUAL VDD rises to the voltage level of the external power supply VDD.

In FIG. 3, current is supplied from the first power line 102 to the second power line 104 at the point in time when the first switching circuit 120 is activated and at the point in time when the second switching circuit 140 is activated. Particularly, since the voltage level of the virtual power supply VIRTUAL VDD is in a fully high level state at the point in time when the second switching circuit 140 is activated, the amount of current that is supplied from the first power line 102 to the second power line 104 is not relatively large. Accordingly, generation of a power noise due to an instantaneous supply of current may be prevented. In order to reduce a power noise due to an instantaneous supply of current at the point in time when the first switching circuit 120 is activated, the sizes of the PMOS transistors 121 and 122 of the first switching circuit 120 may be designed to be relatively small so that driving capabilities of the PMOS transistors 121 and 122 are relatively small. For example, the sizes of the PMOS transistors 121 and 122 of the first switching circuit 120 may be designed to be smaller than those of the PMOS transistors 141, 142, and 143 of the second switching circuit 140.

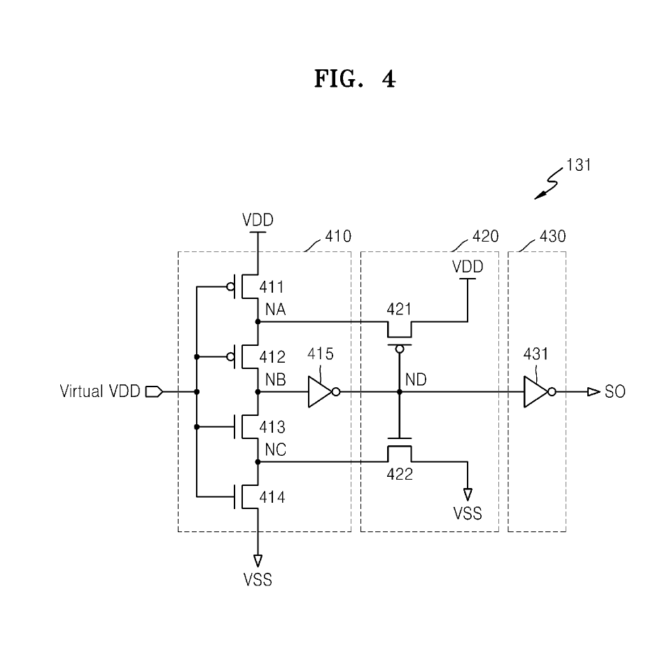

FIG. 4 is a circuit diagram of an example embodiment of the Schmitt trigger circuit 131 of FIG. 1.

Referring to FIG. 4, the Schmitt trigger circuit 131 includes an input portion 410, a hysteresis width control portion 420, and an output portion 430. The input portion 410 includes first and second PMOS transistors 411 and 412 and first and second n-type metal oxide semiconductor (NMOS) transistors 413 and 414, which are serially connected between the power supply voltage VDD and the ground voltage VSS, and an inverter 415 that is connected to a second connection node NB between the second PMOS transistor 412 and the first NMOS transistor 413. Gates of the first and second PMOS transistors 411 and 412 and gates of the first and second NMOS transistors 413 and 414 are connected to the virtual power supply VIRTUAL VDD.

The hysteresis width control portion 420 includes a third PMOS transistor 421 that is connected to the power supply voltage VDD and a first connection node NA between the first PMOS transistor 411 and the second PMOS transistor 412, and a third NMOS transistor 422 that is connected to the ground voltage VSS and a third connection node NC between the first NMOS transistor 413 and the second NMOS transistor 414. A gate of the third PMOS transistor 421 and a gate of the third NMOS transistor 422 are connected to an output node ND of the first inverter 415. The output portion 430 that is a driving portion includes a second inverter 431 that is connected between the output node ND of the first inverter 415 and the output signal SO of the Schmitt trigger circuit 131.

An operation of the Schmitt trigger circuit 131 is described with reference to FIG. 2. When the voltage level of the virtual power supply VIRTUAL VDD is lower than the second trigger point VT2, the first and second PMOS transistors 411 and 412 are turned on. Thus, the voltage levels of the first and second connection nodes NA and NB each transition to a logic high level, a voltage level of the output node ND of the first inverter 415 transitions to a logic low level, and a voltage level of the output signal SO of the Schmitt trigger circuit 131 transitions to a logic high level.

The third PMOS transistor 421 is turned on by the logic low level of the output node ND of the first inverter 415, and thus, a voltage at logic high level is fed back to the first connection node NA. As the voltage level of the virtual power supply VIRTUAL VDD increases until it reaches the first trigger point VT1, the first and second connection nodes NA and NB each maintain the logic high level by feedback driving capabilities of the third PMOS transistor 421 and the second PMOS transistor 412. In addition, the output node ND of the first inverter 415 remains at the logic low level and the output signal SO of the Schmitt trigger circuit 131 remains at the logic high level.

Then, when the voltage level of the virtual power supply VIRTUAL VDD increases to a voltage level higher than the first trigger point VT1 and then reaches the voltage level of the power supply VDD, the NMOS transistors 413 and 414 are turned on. Thus, the voltage levels of the second and third connection nodes NB and NC each become a logic low level, the voltage level of the output node ND of the first inverter 415 becomes a logic high level, and the voltage level of the output signal SO of the Schmitt trigger circuit 131 becomes a logic low level.

The third NMOS transistor 422 is turned on by the logic high level of the output node ND of the first inverter 415, and thus, a voltage at logic low level is fed back to the third connection node NC. As the voltage level of the virtual power supply VIRTUAL VDD decreases until it reaches the second trigger point VT2, the second and third connection nodes NB and NC each maintain the logic low level by feedback driving capabilities of the third NMOS transistor 422 and the first NMOS transistor 413. In addition, the output node ND of the first inverter 415 remains at logic level high and the output signal SO of the Schmitt trigger circuit 131 remains at logic level low.

When the voltage level of the virtual power supply VIRTUAL VDD, which previously increased to the voltage level of the power supply VDD, decreases and then is lower than the first trigger point VT1, the first and second NMOS transistors 413 and 414 are turned off, and the first and second PMOS transistors 411 and 412 are turned on. Thus, the voltage levels of the first and second connection nodes NA and NB each transition to a logic high level, the voltage level of the output node ND of the first inverter 415 transitions to a logic low level, and the voltage level of the output signal SO of the Schmitt trigger circuit 131 transitions to a logic high level.

The first trigger point VT1 may be adjusted by using the feedback driving capabilities of the second and third PMOS transistors 412 and 421. For example, when the driving capability of the third PMOS transistor 421 is greater than that of the second PMOS transistor 412, the voltage level of the first trigger point VT1 may be increased. The second trigger point VT2 may be adjusted by using the feedback driving capabilities of the first and third NMOS transistors 413 and 422. For example, when the driving capability of the third NMOS transistor 422 is greater than that of the first NMOS transistor 413, the voltage level of the second trigger point VT2 may be decreased. Accordingly, a hysteresis width Vth of the Schmitt trigger circuit 131 may be adjusted.

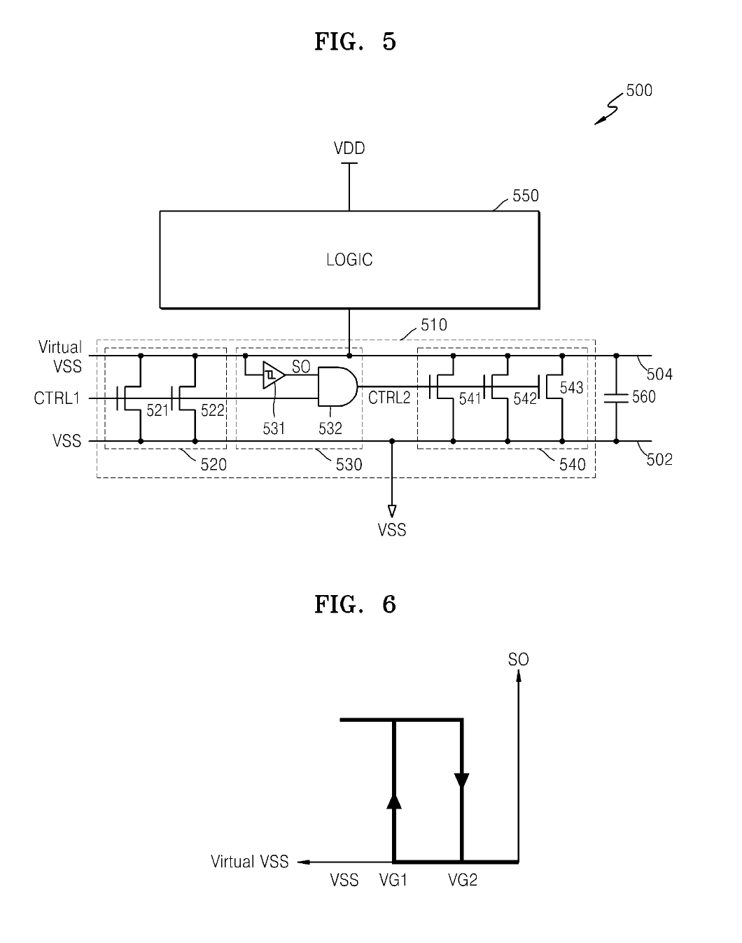

FIG. 5 is a diagram of a semiconductor integrated circuit 500 including a power gating circuit according to another example embodiment of inventive concepts.

Referring to FIG. 5, the semiconductor integrated circuit 500 includes a power gating circuit 510, which is connected between a first ground line 502 and a second ground line 504, and a logic circuit 550. The first ground line 502 is connected to an external ground voltage VSS, and the second ground line 504 is connected to a virtual ground voltage VIRTUAL VSS of the logic circuit 550. The virtual ground voltage VIRTUAL VSS of the logic circuit 550 may be set to have the same or substantially the same voltage level as the external ground voltage VSS.

The power gating circuit 510 includes a first switching circuit 520, a control signal generation circuit 530, and a second switching circuit 540. The first switching circuit 520 includes one or more NMOS transistors 521 and 522 that are connected between the first ground line 502 and the second ground line 504. Gates of the NMOS transistors 521 and 522 are connected to a first control signal CTRL1.

The first control signal CTRL1 may be provided by a CPU according to the need for operation of the logic circuit 550. That is, the CPU may determine whether the operation of the logic circuit 550 is needed and then provide, based on the determination, the first control signal CTRL1 to ground or un-ground the logic circuit 550 (to put the logic circuit 550 into a ground-on or ground-off state. The first control signal CTRL1 may be provided at a logic high level so that the logic circuit 550 enters into a ground-on state of the logic circuit 550, and may be provided to at a logic low level so that the logic circuit 550 enters into a ground-off state.

In the first switching circuit 520, the NMOS transistors 521 and 522 are turned on in response to the first control signal CTRL1 transitioning to a logic high level, and the virtual ground voltage VIRTUAL VSS of the second ground line 504 is connected to the external ground voltage VSS of the first ground line 502 through the turned-on NMOS transistors 521 and 522. The NMOS transistors 521 and 522 are turned off in response to the first control signal CTRL1 transitioning to a logic low level, and the virtual ground voltage VIRTUAL VSS of the second ground line 504 is cut off from the external ground voltage VSS of the first ground line 502 by the turned-off NMOS transistors 521 and 522.

The control signal generation circuit 530 includes a Schmitt trigger circuit 531 that is connected to the second ground line 504, and an AND gate (also referred to herein as a logic gate circuit) 532 that receives the first control signal CTRL1 and an output signal SO of the Schmitt trigger circuit 531. The Schmitt trigger circuit 531 has a voltage level detection function using hysteresis characteristics.

FIG. 6 is a diagram illustrating an example operation waveform of the Schmitt trigger circuit 531. As shown in FIG. 6, the Schmitt trigger circuit 531 has two trigger points, e.g., first and second trigger points VG1 and VG2, according to a voltage level of the virtual ground voltage VSS of the second ground line 504. According to the hysteresis characteristics, the first trigger point VG1 occurring when a voltage level of the virtual ground voltage VIRTUAL VSS falls from a high value to a low value is lower than the second trigger point VG2 occurring when the voltage level of the virtual ground voltage VIRTUAL VSS rises from the low value to the high value. The Schmitt trigger circuit 531 may generate the output signal SO at a logic high level at the first trigger point VG1, and may generate the output signal SO at a logic low level at the second trigger point VG2.

The AND gate (also referred to herein as a logic gate circuit) 532 receives the output signal SO of the Schmitt trigger circuit 531 and the first control signal CTRL1, and outputs a second control signal CTRL2. A voltage level of the second control signal CTRL2 transitions to a logic high level in response to the output signal SO transitioning to a logic high level at the first trigger point VG1 while the first control signal CTRL1 is at a logic high level, which results in the ground-on state of the logic circuit 550. The voltage level of the second control signal CTRL2 transitions to a logic low level in response to the output signal SO transitioning to a logic low level at the second trigger point VG2 while the first control signal CTRL1 is at a logic low level, which results in the ground-on state of the logic circuit 550. Also, the voltage level of the second control signal CTRL2 transitions to a logic low level in response to the first control signal CTRL1 transitioning to a logic low level, which results in the ground-off state of the logic circuit 550.

The second switching circuit 540 includes one or more NMOS transistors 541, 542, and 543 that are connected between the first ground line 502 and the second ground line 504. Gates of the NMOS transistors 541, 542, and 543 are connected to the second control signal CTRL2. In the second switching circuit 540, the NMOS transistors 541, 542, and 543 are turned on in response to the second control signal CTRL2 transitioning to a logic high level, and the virtual ground voltage VIRTUAL VSS of the second ground line 504 is connected to the external ground voltage VSS of the first ground line 502 through the turned-on NMOS transistors 541, 542, and 543. The NMOS transistors 541, 542, and 543 are turned off in response to the second control signal CTRL2 transitioning to a logic low level, and the virtual ground voltage VIRTUAL VSS of the second ground line 504 is cut off from the external ground voltage VSS of the first ground line 104 by the turned-off NMOS transistors 541, 542, and 543.

The NMOS transistors 521, 522, 541, 542, and 543, which constitute the first and second switching circuits 520 and 540 of the power gating circuit 510, may be referred to as PGCs.

The logic circuit 550 may be composed of, for example, any one of various intellectual property (IP) blocks that are embedded in a system such as a mobile terminal. The mobile terminal may be a mobile phone, a personal mobile terminal, a mobile personal computer (PC), etc. The mobile terminal may provide various functions, such as a multimedia function for reproducing music, movies, camera images, etc. and a function for sending and receiving text messages and voice messages, as well as a voice call function and a video conferencing function.

A stabilization capacitor 560 is connected between the second ground line 504, to which the virtual ground voltage VIRTUAL VSS of the logic circuit 550 is connected, and the external ground voltage VSS. The stabilization capacitor 560 prevents a noise occurring in the virtual ground voltage VIRTUAL VSS from influencing an operation of the logic circuit 550.

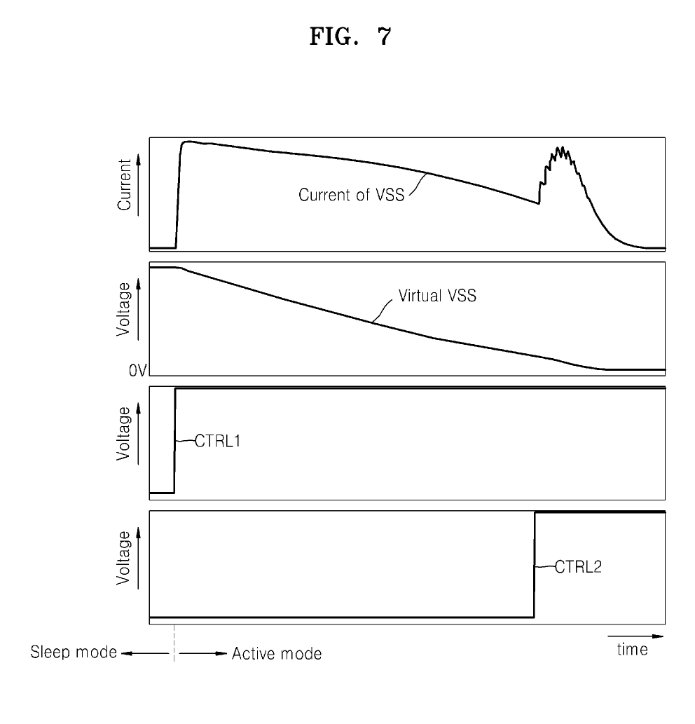

FIG. 7 is a diagram illustrating an electrical potential of the virtual ground voltage VIRTUAL VSS according to the example operation of the power gating circuit 510 of FIG. 5.

Referring to FIG. 7, a voltage level of the first control signal CTRL1 transitions to a logic low level when a sleep mode is activated in which the logic circuit 550 is in the ground-off state. A voltage level of the second control signal CTRL2 also transitions to a logic low level when the first control signal CTRL1 transitions to a logic low level. Accordingly, the NMOS transistors 521 and 522 of the first switching circuit 520 and the NMOS transistors 541, 542, and 543 of the second switching circuit 540 are turned off, and thus, the first ground line 502 and the second ground line 504 are cut off from each other.

Then, the voltage level of the first control signal CTRL1 transitions to a logic high level when an active mode is activated in which the logic circuit 550 is in the ground-on state. The NMOS transistors 521 and 522 of the first switching circuit 520 are turned on in response to the first control signal CTRL1 transitioning to a logic high level. The virtual ground voltage VIRTUAL VSS of the second ground line 504 is discharged to the external ground voltage VSS of the first ground line 502 through the turned-on NMOS transistors 521 and 522, and thus, a voltage level of the virtual ground voltage VIRTUAL VSS gradually decreases.

When the voltage level of the virtual ground voltage VIRTUAL VSS decreases and then reaches the first trigger point VG1 of the Schmitt trigger circuit 531, the voltage level of the second control signal CTRL2 that is generated from the control signal generation circuit 530 transitions to a logic high level. The NMOS transistors 541, 542, and 543 of the second switching circuit 540 are turned on in response to the second control signal CTRL2 transitioning to a logic high level. The virtual ground voltage VIRTUAL VSS of the second ground line 504 is additionally discharged to the external ground voltage VSS of the first ground line 502 through the turned-on NMOS transistors 541, 542, and 543. Thus, the voltage level of the virtual ground voltage VIRTUAL VSS falls to the voltage level of the external ground voltage VSS.

In FIG. 7, a current is discharged from the second ground line 504 to the first ground line 502 at the point in time when the first switching circuit 520 is activated and at the point in time when the second switching circuit 540 is activated. Particularly, since the voltage level of the virtual ground voltage VIRTUAL VSS is in a fully low level state at the point in time when the second switching circuit 540 is activated, the amount of current that is discharged from the second ground line 504 to the first ground line 502 is not relatively large. Accordingly, generation of a power noise due to an instantaneous discharge of current may be prevented. In order to reduce a power noise due to an instantaneous discharge of current at the point in time when the first switching circuit 520 is activated, the sizes of the NMOS transistors 521 and 522 of the first switching circuit 520 may be designed to be relatively small so that driving capabilities of the NMOS transistors 521 and 522 are relatively small. For example, the sizes of the NMOS transistors 521 and 522 of the first switching circuit 520 may be designed to be smaller than those of the NMOS transistors 541, 542, and 543 of the second switching circuit 540.

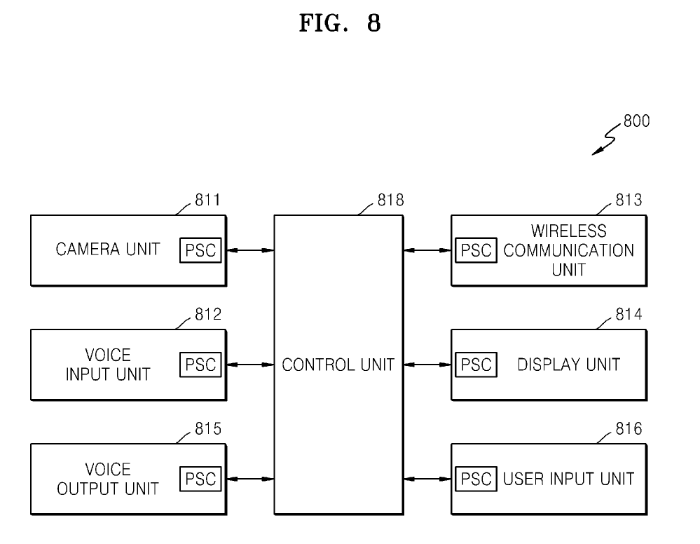

FIG. 8 is a block diagram of a system 800 including a power gating circuit, according to an example embodiment of inventive concepts.

Referring to FIG. 8, the system 800 is a mobile terminal including a wireless network communication function, and may be implemented as various types of apparatuses such as a mobile phone, a mobile PC, a personal mobile terminal, and the like. Hereinafter, the system 800 is referred to as a mobile terminal system 800. The mobile terminal system 800 performs a call function that enables a call between a caller and a receiver. The calling function that is performed by the mobile terminal system 800 includes a video call function, which enables a call while sending and receiving videos and voices, as well as a voice call function.

Examples of a communication method that is performed by the mobile terminal system 800 may include wideband code division multiple access (W-CDMA), enhanced data rate for GSM evolution (EDGE), long term evolution (LTE), worldwide interoperability for microwave access (WiMAX), etc. A wireless network may include a base station transmission system for sending or receiving a wireless communication signal to or from each mobile terminal system 800, a base station controller for controlling and administrating the base station transmission system, and a switchboard for performing call switching between each mobile terminal system 800 through the base station controller.

The mobile terminal system 800 includes a camera unit 811, a voice input unit 812, a wireless communication unit 813, a display unit 814, a voice output unit 815, a user input unit 816, and a control unit 818. The camera unit 811, the voice input unit 812, the wireless communication unit 813, the display unit 814, the voice output unit 815, the user input unit 816, and the control unit 818 each may use the logic circuit 150 of FIG. 1 and the logic circuit 550 of FIG. 5.

The camera unit 811 performs a picture-taking operation and then generates an image. The camera unit 811 may include an optical portion including at least one lens through which light passes, and an image sensor that converts light received through the lens into electrical data to generate an image. The image sensor of the camera unit 811 may be a RAW-Bayer and/or CMOS type image sensor, which-is operated by an image processing unit through a sensor interface. The image sensor of the camera unit 811 may include a plurality of photodetectors formed to convert light detected by the image sensor into an electrical signal. The image sensor may further include a color filter array that captures color information by filtering light captured by the image sensor.

The voice input unit 812 includes, for example, a voice sensor such as a microphone, and receives a voice input necessary for a voice call.

The wireless communication unit 813 is connected to a wireless network, and performs a communication with a terminal of the other party by using a given (or alternatively predetermined) wireless communication method. During a phone call, the wireless communication unit 813 transmits video call data, which includes an image generated by the camera unit 811 and/or a voice input through the voice input unit 812, to a terminal of the other party according to a control of the control unit 818, and receives video call data including a video and/or a voice input from the terminal of the other party.

The display unit 814 displays data on a screen, and may include a display device such as a liquid crystal display (LCD) or the like. The display unit 814 may display an image generated by the camera unit 811 under the control of the control unit 818.

The voice output unit 815 outputs a voice, and may include a voice output device such as an internal speaker or the like. Also, the voice output unit 815 may further include a connector for connection to an external voice output device such as an earphone, a headset, an external speaker, or the like, and may output a voice to a connected external voice output device. The voice output unit 815 may output a voice received from a terminal of the other party according to a control of the control unit 818 during a voice call or a video call.

The user input unit 816 receives a user input for an operation of the mobile terminal system 800. The user input unit 816 may include a keypad including a plurality of keys for inputting numbers and characters. The keypad may be implemented in a form of a touch pad. The user input unit 816 may further include a sensor for sensing a user's motion or gesture on the display unit 814 as a user input. The sensor of the user input unit 816 may be implemented with a touch screen that is disposed to overlap with a panel type display device of the display unit 814, such as the LCD.

The control unit 818 performs an overall control of the mobile terminal system 800. When a call function is selected by a user's input through the user input unit 816, the control unit 818 requests a call switching for a terminal of the other party through the wireless communication unit 813 with reference to an input phone number. When the call switching is performed, the control unit 818 transmits call data including an image generated by the camera unit 811 and/or a voice input through the voice input unit 812 to a terminal of the other party through the wireless communication unit 813, and performs a control to output an image and/or a voice included in call data, which are received from the terminal of the other party through a wireless communication unit 813, to the display unit 814 and/or the voice output unit 815.

The control unit 818 performs a plurality of image processing operations through an image processing pipeline with respect to image data captured by the image sensor of the camera unit 811. A processed resulting image may be displayed on the display unit 814. As a resolution and a frame rate of image data that is processed increases, an image signal processing system corresponding thereto is required.

The camera unit 811, the voice input unit 812, the wireless communication unit 813, the display unit 814, the voice output unit 815, and the user input unit 816 of the mobile terminal system 800 each may include a power gating circuit PSC. The control unit 818 of the mobile terminal system 800 may provide a first control signal that determines power-on or off states of the camera unit 811, the voice input unit 812, the wireless communication unit 813, the display unit 814, the voice output unit 815, and the user input unit 816. Also, the control unit 818 may provide a first control signal that determines ground-on or ground-off states of the camera unit 811, the voice input unit 812, the wireless communication unit 813, the display unit 814, the voice output unit 815, and the user input unit 816.

The power gating circuit PSC may be connected between a first power line, to which an external power supply is connected, and second power lines of the camera unit 811, the voice input unit 812, the wireless communication unit 813, the display unit 814, the voice output unit 815, and the user input unit 816. The power gating circuit PSC may include a first switching circuit that connects or separates the first power line and the second power line in response to a first control signal, a control signal generation circuit that generates a second control signal in response to the first control signal and an output signal of a Schmitt trigger circuit which is connected to the second power line, and a second switching circuit that connects or separates the first power line and the second power line in response to the second control signal.

Also, the power gating circuit PSC may be connected between a first ground line, to which an external ground voltage is connected, and second ground lines of the camera unit 811, the voice input unit 812, the wireless communication unit 813, the display unit 814, the voice output unit 815, and the user input unit 816. The power gating circuit PSC may include a first switching circuit that connects or separates the first ground line and the second ground line in response to a first control signal, a control signal generation circuit that generates a second control signal in response to the first control signal and an output signal of a Schmitt trigger circuit which is connected to the second ground line, and a second switching circuit that connects or separates the first ground line and the second ground line in response to the second control signal.

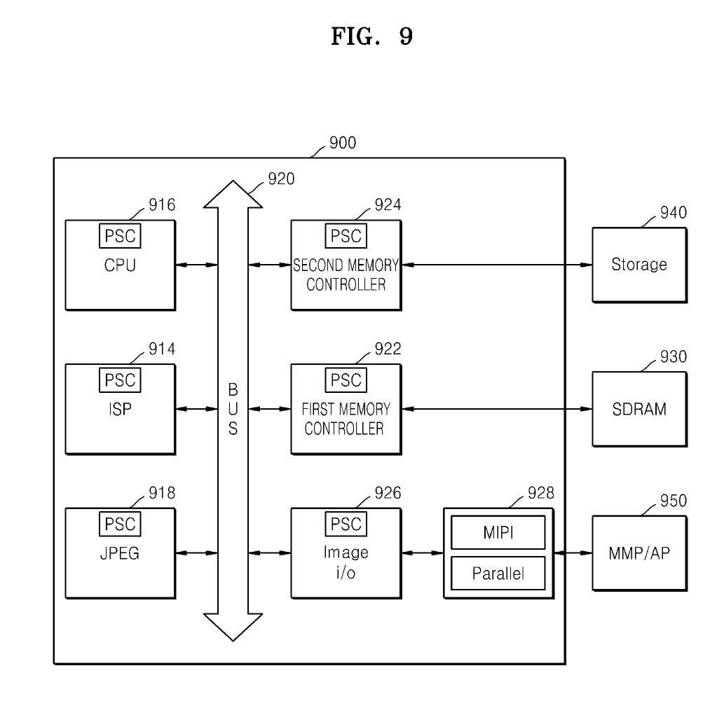

FIG. 9 is a block diagram of a system 900 including a power gating circuit, according to another example embodiment of inventive concepts.

Referring to FIG. 9, the system 900 may be an image processing system that is included in the control unit 818 of FIG. 8. Hereinafter, the system 900 is referred to as an image processing system 900. The image processing system 900 may include an image signal processor (ISP) 914, a CPU 916, an image codec unit 918, first and second memory controllers 922 and 924, an image input and output unit 926, and an interface unit 928. The ISP 914, the image codec unit 918, the first and second memory controllers 922 and 924, the image input and output unit 926, and the interface unit 928 each may use the logic circuit 150 of FIG. 1 and the logic circuit 550 of FIG. 5.

The ISP 914 may include a Bayer processing unit, a red/green/blue (RGB) processing unit, a scaling/rotating/affine-transform processing unit, etc. In order to control a processing of each unit, the ISP 914 may control the size of an image, the depth of a color, a dead pixel alive, a lens shading compensation, an adaptive color interpolation, a color correction, a gamma control, a hue/gain control, an image effect, an auto-exposure, an auto-white balance, etc. Image data processed by the ISP 914 may be transmitted to the image codec unit 918 through a bus 922.

The image codec unit 918 may perform an image encoding and an image decoding using an image format with which it is easy to transmit and store image data. The image codec unit 918 is composed of a joint photographic experts group (JPEG) codec, and thus may generate a high resolution JPEG image. The JPEG codec compresses image data for each block unit. Also, the JPEG codec scans a block data compression stream of a location, which is desired to be decoded, from the beginning of a file, and searches for the location, and then restores and reproduces the block data compression stream of the location.

In a baseline JPEG that corresponds to a minimum requirement of a JPEG compression, image data is converted from an RGB color to a YIQ color, an image of each color component (Y,I,Q) is divided into 8×8 block unit-based macro blocks, and a discrete cosign transform (DCT) is performed on the macro blocks. In addition, DCT coefficients that are obtained by performing the DCT are linearly quantized with different step sizes for each DCT coefficient by using a quantization table to separate a visually more important part and a visually less important part, and the amount of data is reduced by maintaining the more important part and discarding the less important part. 8×8 block data is a minimum coding unit, and the size of block data may be changed when a minimum block unit is changed.

The DCT coefficients quantized in macro block units include 1 direct current (DC) component and 63 alternating current (AC) components. The DC component is obtained by encoding differential signals between a current macro block and an adjacent previous macro block in consideration of a correlation between adjacent signals (Differential Pulse Code Modulation (DPCM)). The AC components are obtained by listing coefficients(??) in line by a zigzag scan for each macro block and then encoding the coefficients(Run-Length Coding).

A JPEG image compressed by a JPEG compression method includes a plurality of macro blocks between which boundaries are formed, and each of the plurality of macro blocks is composed of one DC component and an end of block (EOC) code indicating the end of each macro block. Each of the macro blocks constituting the JPEG image has mutually dependent DC values.

The ISP 914 corrects JPEG image data to suppress a noise thereof. The ISP 914 may adjust DC/AC coefficients of 8×8 block data. In detail, the ISP 914 separates an image area based on DC/AC threshold values from block data, and then reduces noise by adjusting or controlling DC/AC coefficients of the block data (Noise reduction). The ISP 914 reduces a blocky effect by adjusting the AC coefficients. Also, the ISP 914 may apply a brightness enhancement to the block data by adjusting the DC/AC coefficients.

The CPU 916 is a microprocessor including hardware, software, and/or firmware, which are necessary to implement a method of processing the above-stated image data. The CPU 916 may include a graphic processing unit (GPU) (e.g., a video processing unit (VPU)) to handle a series of complicated processes related to the processing of the image data.

The CPU 916 may process a handling and rendering of a graphic image, which is used by various electronic games and other applications. The CPU 916 may receive commands and image data, such as a software application, from a host. The commands are used for specifying a calculation and an operation, which are necessary to generate an image rendered by changing the image data.

The CPU 916 may control an additional process function such as a camera function, a multimedia data reproduction, or the like. The CPU 916 may reduce, magnify, or crop image data to be suitable to the size of the display unit 814 of FIG. 8, and may change the image data to be suitable to a color standard of image data that are displayed on the display unit 814 of FIG. 8.

Commands or image data to be processed by the CPU 916 may be stored in a memory device 930. The memory device 930 may be an external memory device that exists outside of the image processing system 900. The image processing system 900 may control the memory device 930 through the first memory controller 922. The memory device 930 may be a volatile memory such as a synchronous dynamic random access memory (SDRAM). The first memory controller 922 may be an SDRAM controller for controlling an operation of the SDRAM. The memory device 930 may store a basic input output system (BIOS), an operating system (OS), various programs, various applications, or firmware having a user interface function.

The memory device 930 may store original image data that is received from the image sensor of the camera unit 811 illustrated in FIG. 8. The original image data stored in the memory device 930 may be provided to the ISP 914.

The memory device 930 may be used for buffering or caching during the operation of the image processing system 900. For example, the memory device 930 may include at least one frame buffer for buffering image data when the image data is output to the display unit 814 of FIG. 8. That is, the memory device 930 may store image data before the processing of the image data, during the processing of the image data, and after the processing of the image data.

In addition to being connected to the memory device 930, the image processing system 900 may be connected to a non-volatile storage device 940 to permanently store image data and/or commands. The image processing system 900 is connected to the non-volatile storage device 940 through the second memory controller 924. The non-volatile storage device 940 is controlled by the second memory controller 924. The non-volatile storage device 940 may be an external storage device that exists outside of the image processing system.

The non-volatile storage device 940 may include a flash memory, a hard drive, an optical, magnetic, and/or solid state storage medium, or a combination thereof. The second memory controller 924 may be a flash memory controller for controlling a flash memory. Although in FIG. 9, the non-volatile storage device 940 is illustrated as a single device, the non-volatile storage device 940 may include a combination of two or more of the above-stated storage devices, which operates in connection with the image processing system 900.

The non-volatile storage device 940 may be used for storing firmware, data files, image data, software programs and applications, wireless connection information, personal information, user preferences, and/or any other data. Image data stored in the non-volatile storage device 940 and/or the memory device 930 may be processed by the image processing system 900 before being output onto a display device.

Through the image processing system 900, the memory device 930 may not only store original image data captured through the image sensor of the camera unit 811 of FIG. 8, but also may store image data stored in an electronic device such as a computer or the like. The memory device 930 may transmit original image data or JPEG image data stored in the memory device 930 to the display unit 814 of FIG. 8 to display it on the display unit 814. The display unit 814 may display image data or may display menus and commands as a part of a user interface.

A multimedia device, such as the camera unit 811, a computer, or the display unit 814, may be controlled by a multimedia processor (MMP) or an application processor (AP) to perform an additional function such as a camera function, a multimedia file reproduction function, a three dimensional (3D) graphic function, or the like. An operation mode of the camera function that is performed by the MMP may be divided into a preview mode and a multimedia operation mode. The preview mode is a mode for previewing before photographing by a camera, and the multimedia operation mode is a mode for performing a photographing operation by a photographing command input.

The image processing system 900 may be referred to as a front-end processor regarding image data. Since an MMP/AP 950 corresponds to a subsequent processor, the MMP/AP 950 may be referred to as a back-end processor. The back-end processor 950 may be connected to the camera unit 811 of FIG. 8, a computer, and/or the display unit 814 of FIG. 8. The image processing system 900 transmits image data stored in the memory device 930 to the back-end processor 950 through the image input and output unit 926.

The image input and output unit 926 may transmit original image data, which are output from the image sensor of the camera unit 811 of FIG. 8, to the back-end processor 950. The image input and output unit 926 may transmit imaged image adjusted to be suitable to the size of the display unit 814 that is connected to the back-end processor 950. Also, the image input and output unit 926 may output image data adjusted to be suitable to a color standard of image data that are displayed on the display unit 814 of FIG. 8. The interface unit 928 for performing an image data interchange may be connected between the image input and output unit 926 and the back-end processor 950.

The interface unit 928 may include a mobile industry processor interface (MIPI) for transmitting a frame, which is an image data transmission unit, and/or a parallel interface. The frame may include addresses and essential protocol control information as well as actual image information. The frame is transmitted in bit units, and may include a header field and a trailer file before and after data. The parallel interface is used when transmitting image data having a low resolution and a low frame rate. The MIPI that is a high speed serial interface is used when transmitting image data having a high resolution and a high frame rate.

The ISP 914, the image codec unit 918, the first and second memory controllers 922 and 924, the image input and output unit 926, and the interface unit 928, which may be included in the control unit 818, each may include a power gating circuit (PSC). The CPU 916 may provide a first control signal that determines power-on or off states of the ISP 914, the image codec unit 918, the first and second memory controllers 922 and 924, the image input and output unit 926, and the interface unit 928. Also, the CPU 916 may provide a first control signal that determines ground-on or off states of the ISP 914, the image codec unit 918, the first and second memory controllers 922 and 924, the image input and output unit 926, and the interface unit 928.

The power gating circuit PSC may be connected between a first power line, to which an external power supply is connected, and a second power line of the ISP 914, the image codec unit 918, the first and second memory controllers 922 and 924, the image input and output unit 926, and the interface unit 928. The power gating circuit PSC may include a first switching circuit that connects or separates the first power line and the second power line in response to a first control signal, a control signal generation circuit that generates a second control signal in response to the first control signal and an output signal of a Schmitt trigger circuit which is connected to the second power line, and a second switching circuit that connects or separates the first power line and the second power line in response to the second control signal.

Also, the power gating circuit PSC may be connected between a first ground line, to which an external ground voltage is connected, and a second ground line of the ISP 914, the image codec unit 918, the first and second memory controllers 922 and 924, the image input and output unit 926, and the interface unit 928. The power gating circuit PSC may include a first switching circuit that connects or separates the first ground line and the second ground line in response to a first control signal , a control signal generation circuit that generates a second control signal in response to the first control signal and an output signal of a Schmitt trigger circuit which is connected to the second ground line, and a second switching circuit that connects or separates the first ground line and the second ground line in response to the second control signal.

Although example embodiments may be described herein with regard to specific logic gates (e.g., AND and/or OR gates), example embodiments are not limited to this implementation. Rather, other logic gate circuits may be used as desired by a person having ordinary skill in the art to achieve similar, substantially similar or the same functionality.

While inventive concepts have been particularly shown and described with reference to example embodiments thereof, it will be understood by those of ordinary skill in the art that various changes in form and details may be made therein without departing from the spirit and scope of the present invention as defined by the following claims.

What is claimed is:

1. A power gating circuit comprising:
a first power line;
a second power line;
a first switching circuit configured to connect the first power line to the second power line or separate the first power line from the second power line in response to a first control signal indicative of a power-on or a power-off state of a logic circuit;
a control signal generation circuit configured to generate a second control signal in response to the first control signal and an output signal from a Schmitt trigger circuit, the Schmitt trigger circuit being configured to detect a voltage level of the second power line; and
a second switching circuit configured to connect the first power line to the second power line or separate the first power line from the second power line in response to the second control signal.

2. The power gating circuit of claim 1, wherein a driving capability of the first switching circuit is smaller than a driving capability of the second switching circuit.

3. The power gating circuit of claim 1, wherein the first switching circuit comprises:
at least one transistor; wherein
a gate of the at least one transistor is configured to receive the first control signal,
a source of the at least one transistor is connected to the first power line, and
a drain of the at least one transistor is connected to the second power line.

4. The power gating circuit of claim 1, wherein the control signal generation circuit comprises:
the Schmitt trigger circuit having an input terminal connected to the second power line; and
a logic gate circuit configured to receive the first control signal and the output signal from the Schmitt trigger circuit, the logic gate circuit being further configured to output the second control signal.

5. The power gating circuit of claim 1, wherein the second switching circuit comprises:
at least one transistor; wherein
a gate of the at least one transistor is configured to receive the second control signal,
a source of the at least one transistor is connected to the first power line, and
a drain of the at least one transistor is connected to the second power line.

6. A semiconductor integrated circuit comprising:
a first power line;
a second power line; and
a power gating circuit configured to connect the first power line to the second power line or separate the first power line from the second power line, the power gating circuit being further configured to use a Schmitt trigger circuit, the Schmitt trigger circuit being configured to detect a voltage level of the second power line.

7. The semiconductor integrated circuit of claim 6, wherein the first power line is connected to an external power supply.

8. The semiconductor integrated circuit of claim 6, wherein the second power line is connected to a power supply of a logic circuit.

9. The semiconductor integrated circuit of claim 6, wherein the power gating circuit comprises:
a first switching circuit configured to connect the first power line to the second power line or separate the first power line from the second power line in response to a first control signal indicative of a power-on or power-off state of a logic circuit;
a control signal generation circuit configured to generate a second control signal in response to the first control signal and an output signal from the Schmitt trigger circuit that is connected to the second power line; and
a second switching circuit configured to connect the first power line to the second power line or separate the first power line from the second power line in response to the second control signal.

10. The semiconductor integrated circuit of claim 9, wherein a driving capability of the first switching circuit is smaller than a driving capability of the second switching circuit.

11. The semiconductor integrated circuit of claim 9, wherein the first switching circuit comprises:
at least one transistor; wherein
a gate of the at least one transistor is configured to receive the first control signal,
a source of the at least one transistor is connected to the first power line, and
a drain of the at least one transistor is connected to the second power line.

12. The semiconductor integrated circuit of claim 9, wherein the control signal generation circuit comprises:
the Schmitt trigger circuit having an input terminal connected to the second power line; and
a logic gate circuit configured to receive the first control signal and the output signal from the Schmitt trigger circuit, the logic gate circuit being further configured to output the second control signal.

13. The semiconductor integrated circuit of claim 12, wherein the Schmitt trigger circuit comprises:
a first transistor, a second transistor, a third transistor and a fourth transistor, which are serially connected between a power supply voltage and a ground voltage;
a first inverter connected to a first connection node between the second transistor and the third transistor;
a fifth transistor connected to the power supply voltage and a second connection node between the first transistor and the second transistor;
a sixth transistor connected to the ground voltage and a third connection node between the third transistor and the fourth transistor; and
a second inverter connected between an output node of the first inverter, and configured to receive the output signal from the Schmitt trigger circuit.

14. The semiconductor integrated circuit of claim 9, wherein the second switching circuit comprises:
at least one transistor; wherein
a gate of the at least one transistor is configured to receive the second control signal,
a source of the at least one transistor is connected to the first power line, and
a drain of the at least one transistor is connected to the second power line.

15. A semiconductor integrated circuit comprising:
a first ground line;
a second ground line; and
a power gating circuit configured to connect the first ground line to the second ground line or separate the first ground line from the second ground line, the power gating circuit being further configured to use a Schmitt trigger circuit, the Schmitt trigger circuit being configured to detect a voltage level of the second ground line.

16. The semiconductor integrated circuit of claim 15, wherein the first ground line is connected to an external ground voltage.

17. The semiconductor integrated circuit of claim 15, wherein the second ground line is connected to a ground voltage of a logic circuit.

18. The semiconductor integrated circuit of claim 15, wherein the power gating circuit comprises:
a first switching circuit configured to connect the first ground line to the second ground line or separate the first ground line from the second ground line in response to a first control signal indicative of a ground-on or ground-off state of a logic circuit;
a control signal generation circuit configured to generate a second control signal in response to the first control signal and an output signal from the Schmitt trigger circuit that is connected to the second ground line; and
a second switching circuit configured to connect the first ground line to the second ground line or separate the first ground line from the second ground line in response to the second control signal.

19. The semiconductor integrated circuit of claim 18, wherein a driving capability of the first switching circuit is smaller than a driving capability of the second switching circuit.

20. The semiconductor integrated circuit of claim 18, wherein the first switching circuit comprises:
at least one transistor; wherein
a gate of the at least one transistor is configured to receive the first control signal,
a source of the at least one transistor is connected to the first ground line, and
a drain of the at least one transistor is connected to the second ground line.

21. The semiconductor integrated circuit of claim 18, wherein the control signal generation circuit comprises:
the Schmitt trigger circuit having an input terminal connected to the second ground line; and
a logic gate circuit configured to receive the first control signal and the output signal of the Schmitt trigger circuit, the logic gate circuit being further configured to output the second control signal.

22. The semiconductor integrated circuit of claim 18, wherein the second switching circuit comprises:
at least one transistor, wherein
a gate of the at least one transistor is configured to receive the second control signal,
a source of the at least one transistor is connected to the first ground line, and
a drain of the at least one transistor is connected to the second ground line.

23. A system comprising:
a logic circuit;
a first power line connected to an external power supply;
a first ground line connected to an external ground voltage; and
a power gating circuit configured to,
use a Schmitt trigger circuit to detect a voltage level of a second power line or a second ground line of the logic circuit,
connect the first power line to the second power line or separate the first power line from the second power line, and
connect the first ground line to the second ground line or separate the first ground line from the second ground line.

24. The system of claim 23, wherein the power gating circuit comprises:
a first switching circuit configured to connect the first power line to the second power line or separate the first power line from the second power line in response to a first control signal indicative of a power-on or power-off state of the logic circuit;
a control signal generation circuit configured to generate a second control signal in response to the first control signal and an output signal from the Schmitt trigger circuit that is connected to the second power line; and
a second switching circuit configured to connect the first power line to the second power line or separate the first power line from the second power line in response to the second control signal.

25. The system of claim 23, wherein the power gating circuit comprises:
a first switching circuit configured to connect the first ground line to the second ground line or separate the first ground line from the second ground line in response to a first control signal indicative of a ground-on or ground-off state of the logic circuit;
a control signal generation circuit configured to generate a second control signal in response to the first control signal and an output signal from the Schmitt trigger circuit that is connected to the second ground line; and
a second switching circuit configured to connect the first ground line to the second ground line or separate the first ground line from the second ground line in response to the second control signal.

26. A power gating circuit comprising:
a first switching circuit configured to selectively connect a first voltage line and a second voltage line in response to a first control signal;
a Schmitt trigger circuit configured to generate an output signal based on a detected voltage level of the second voltage line;
a control signal generation circuit configured to generate a second control signal in response to the first control signal and the output signal from the Schmitt trigger circuit; and
a second switching circuit configured to selectively connect the first voltage line and the second voltage line in response to the second control signal.

27. The power gating circuit of claim 26, wherein the first and second voltage lines are power lines.

28. The power gating circuit of claim 26, wherein the first and second voltage lines are ground lines.

29. The power gating circuit of claim 26, wherein the Schmitt trigger circuit is configured to generate the output signal having a first logic level when the detected voltage level reaches a first voltage trigger point, and configured to generate the output signal having a second logic level when the detected voltage level reaches a second voltage trigger point, the first voltage trigger point being greater than the second voltage trigger point and the first logic level being different from the second logic level.

30. A system comprising:
a logic circuit; and
the power gating circuit of claim 26 configured to apply an operating voltage to the logic circuit.
